(19) United States
(12) Patent Application Publication
(10) Pub. No.: US 2026/0327794 A1
(43) Pub. Date: Oct. 22, 2026

(54) PRECURSOR VESSEL SYSTEMS AND METHODS

(71) Applicant: ASM IP Holding B.V., Almere (NL)

(72) Inventor: Yeonsu Rhee, Phoenix, AZ (US)

(21) Appl. No.: 19/648,087

(22) Filed: Apr. 15, 2026

Related U.S. Application Data
(60) Provisional application No. 63/791,056, filed on Apr. 18, 2025.

(51) Int. Cl. C23C 16/448; C23C 16/455

(52) U.S. Cl. CPC C23C 16/4481; C23C 16/45561

(57) ABSTRACT

A method can comprise heating a source vessel comprising a solid precursor to a predetermined temperature; subliming or vaporizing a first portion of the solid precursor in the source vessel to produce a precursor gas in response to heating the source vessel, causing the overhead volume in the interior space to increase to a second volume; flowing the precursor gas out of the source vessel; and/or moving the movable base in response to subliming or vaporizing the first portion of the nongaseous precursor to decrease the overhead volume toward the first volume.

### CROSS-REFERENCE TO RELATED APPLICATIONS

This application is a nonprovisional of, and claims priority to and the benefit of, U.S. Provisional Patent Application No. 63/791,056, filed Apr. 18, 2025 and entitled “PRECURSOR VESSEL SYSTEMS AND METHODS,” which is hereby incorporated by reference herein.

### FIELD

The present disclosure generally relates to systems and methods for gas-phase processing. More particularly, the disclosure relates to methods and systems for delivering a precursor to gas-phase reactor systems.

### BACKGROUND

Semiconductor manufacturing processes such as chemical vapor deposition (CVD) and atomic layer deposition (ALD) can involve deposition of thin film on a semiconductor wafer (also referred to herein as a “substrate”). During processing, the wafer is exposed to one or more precursors in a reaction chamber to deposit the thin layers of material. A precursor can be stored in a delivery or source vessel, from which precursor is delivered to a reaction chamber for processing. As a precursor is added to or removed from the source vessel, an unoccupied volume within the source vessel can change, which can change the conditions within the source vessel (e.g., temperature and/or pressure). Such changes can cause undesired changes in precursor delivery (e.g., a rate of delivery of the precursor to a reaction chamber) during processing.

### SUMMARY

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

Systems and methods are disclosed relating to a reactor system. In various examples, a reactor system can comprise a source vessel comprising a nongaseous (e.g., solid or liquid) precursor; a reaction chamber fluidly coupled to the source vessel via a gas line such that a precursor gas sublimed or vaporized from the nongaseous precursor can flow from the source vessel to the reaction chamber; and/or a pressure sensor coupled to the gas line and/or source vessel configured to measure a pressure of the precursor gas flowing through or within the gas line and/or source vessel.

In various examples, a method can comprise heating a source vessel to a predetermined temperature, wherein the source vessel comprises a movable base and a wall system at least partially defining an interior space with a nongaseous precursor disposed therein, wherein the interior space comprises an overhead volume above the precursor having a first volume; subliming and/or vaporizing a first portion of the nongaseous precursor in the source vessel to produce a precursor gas in response to the heating the source vessel, causing the overhead volume in the interior space to increase to a second volume; flowing the precursor gas out of the source vessel; and/or moving the movable base in response to the subliming or vaporizing the first portion of the nongaseous precursor to decrease the overhead volume toward the first volume. Moving the movable base can occur substantially simultaneously to at least one of (a) subliming or vaporizing the first portion of the nongaseous precursor or (b) flowing the precursor gas out of the source vessel. The method can further comprise maintaining the overhead volume at a substantially constant volume. The method can further comprise adding more of the nongaseous precursor into the source vessel, thus decreasing the overhead volume in the interior space; and/or lowering the movable base to increase the overhead volume toward the first volume. In various examples, moving the movable base can comprise applying pressure to the moveable base in response to the flowing the precursor gas out of the source vessel. The movable base can comprise a telescoping structure, wherein moving the movable base comprises expanding the telescoping structure into the second volume as the precursor gas flows out of the source vessel; and/or lowering/collapsing the telescoping structure as nongaseous precursor is added to the source vessel. The movable base can be configured to move between a raised position and a lower position.

In various examples, a method can comprise adding a nongaseous precursor into an interior space of a source vessel, wherein the source vessel comprises a movable base and a wall system at least partially defining the interior space, wherein the interior spaces comprises an overhead volume above the nongaseous precursor having a first volume. The overhead volume in the interior space can decrease to a second volume in response to the adding the nongaseous precursor. The method can further comprise moving the movable base to increase the overhead volume in response to the adding the nongaseous precursor into the interior space. The method can further comprise maintaining the overhead volume at a substantially constant level. The method can further comprise monitoring, by a processor, the overhead volume in the interior space; and/or detecting, by the processor, a change in the overhead volume in the interior space in response to the adding the nongaseous precursor to the interior space. The moving the movable base can be in response to the detecting the change in the overhead volume. The method can further comprise removing a portion of the nongaseous precursor from the interior space of the source vessel, thus increasing the overhead volume in the interior space; and/or moving the movable base in response to the increasing the overhead volume.

In various examples, a method can comprise adding a nongaseous precursor into an interior space of a source vessel, wherein the source vessel comprises a movable base and a wall system at least partially defining the interior space, wherein the interior spaces comprises an overhead volume above the nongaseous precursor having a first volume; moving the movable base, wherein the nongaseous precursor is disposed on the movable base; and/or agitating the nongaseous precursor. The method can further comprise distributing the nongaseous precursor at least partially across the movable base in response to the agitating the nongaseous precursor. The method can further comprise subliming and/or vaporizing a first portion of the nongaseous precursor in the source vessel to produce a precursor gas; flowing the precursor gas out of the source vessel in response to the subliming or vaporizing of the first portion of the nongaseous precursor, causing the overhead volume in the interior space to increase; and/or moving the movable base in response to the flowing the precursor gas out of the source vessel to decrease the overhead volume.

For the purpose of summarizing the disclosure and the advantages achieved over the prior art, certain objects and advantages of the disclosure have been described herein above. Of course, it is to be understood that not necessarily all such objects or advantages may be achieved in accordance with any particular example of the disclosure. Thus, for example, those skilled in the art will recognize that the disclosure may be embodied or carried out in a manner that achieves or optimizes one advantage or group of advantages as taught or suggested herein.

All of these examples are intended to be within the scope of the disclosure herein disclosed. These and other examples will become readily apparent to those skilled in the art from the following detailed description of certain examples having reference to the attached figures, the disclosure not being limited to any particular example(s) disclosed.

### BRIEF DESCRIPTION OF THE DRAWING FIGURES

A more complete understanding of the present technology may be derived by referring to the detailed description when considered in connection with the following illustrative figures. In the following figures, like reference numbers refer to similar elements and steps throughout the figures.

FIG. 1A is a schematic diagram of a reactor system, in accordance with various examples.

FIG. 1B is a schematic diagram of the source vessel of the reactor system of FIG. 1A, in accordance with various examples.

FIG. 2 representatively illustrates a source vessel with a movable base, in accordance with various examples.

FIG. 3A representatively illustrates a movable base of a source vessel in a fully contracted position, in accordance with various examples.

FIG. 3B representatively illustrates a movable base of a source vessel in a first intermediate position, in accordance with various examples.

FIG. 3C representatively illustrates a movable base of a source vessel in a second intermediate position, in accordance with various examples.

FIG. 3D representatively illustrates a movable base of a source vessel in a third intermediate position, in accordance with various examples.

FIG. 3E representatively illustrates a movable base of a source vessel in a fully expanded position, in accordance with various examples.

FIG. 4 depicts a method including a source vessel comprising a movable base, in accordance with various examples.

FIG. 5 depicts a method for agitating a nongaseous precursor in a source vessel, in accordance with various examples.

It will be appreciated that elements in the figures are illustrated for simplicity and clarity and have not necessarily been drawn to scale. For example, the relative size of some of the elements in the figures may be exaggerated relative to other elements to help improve understanding of illustrated examples of the present disclosure.

### DETAILED DESCRIPTION

The description of examples of methods, structures, devices, and systems provided below is merely exemplary and is intended for purposes of illustration only—the following description is not intended to limit the scope of the disclosure or the claims. Moreover, recitation of multiple examples having stated features is not intended to exclude other examples having additional features or other examples incorporating different combinations of the stated features. For example, various examples are set forth as embodiments and may be recited in the dependent claims. Unless otherwise noted, the examples or components thereof may be combined or may be applied separately from each other. Methods may include the disclosed steps in any suitable and/or desired order or combination (including mixing/combining steps from methods depicted in separate figures).

As used herein, the term “and/or” includes any and all combinations of one or more of the associated listed items. Unless otherwise noted, expressions such as “at least one of,” when preceding a list of elements, modify the entire list of elements and do not necessarily modify the individual elements of the list.

As used herein, the terms “includes,” “comprises,” “including,” and/or “comprising” specify the presence of stated features, integers, steps, processes, members, components, and/or groups thereof, but do not preclude the presence or addition of one or more other features, integers, steps, processes, members, components, and/or groups thereof. In this disclosure, any defined meanings do not necessarily exclude ordinary and customary meanings in some examples.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

In some examples, “film” refers to a layer extending in a direction perpendicular to a thickness direction. In some examples, “layer” refers to a material having a certain thickness formed on a surface and can be a synonym of a film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. The layer or film can be continuous—or not. Further, a single film or layer can be formed using one or more deposition cycles and/or one or more deposition and treatment cycles.

As used herein, the term “structure” can refer to a partially or completely fabricated device structure. By way of examples, a structure can be a substrate or include a substrate with one or more layers and/or features formed thereon.

In this disclosure, any two numbers of a variable can constitute a workable range of the variable, any ranges indicated may include or exclude the endpoints, and all ranges and ratio limits disclosed herein may be combined. Additionally, any values of variables indicated (regardless of whether they are indicated with “about” or not) may refer to precise values or approximate values and include equivalents, and may refer to average, median, representative, majority, etc. in some examples. Unless specifically stated otherwise, references to “a,” “an,” and/or “the” may include one or more than one, and references to an item in the singular may also include the item in the plural. When referring to components of systems discussed herein, the term “coupled” refers to direct coupling or indirect coupling with other intervening elements, as appropriate. Unless otherwise indicated, the terms “first,” “second,” etc., and/or “primary,” “secondary,” etc., are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item. Further, reference to, e.g., a “first” item and a “second” item does not mean that there are no intervening items, and such intervening items may be present.

Reactor systems used for ALD, CVD, and/or the like, may be used for a variety of applications, including depositing and etching materials on a substrate surface. A reactor system can comprise a precursor vessel (i.e., delivery vessel or a source vessel), in which a chemical precursor can be stored, and from which the chemical precursor can be delivered to another component of the reactor system (e.g., a reaction chamber) for processing. The precursor vessel can comprise a source vessel configured to house a solid or liquid (i.e., a nongaseous) precursor (“precursor vessel,” “delivery vessel,” and/or “source vessel” may be used interchangeably herein).

The source vessel can include the source precursor (which may also be referred to as “reactant,” “chemical,” or “chemical precursor”), which can be a solid (e.g., in powder form) (which may also be referred to as “solid precursor”) or liquid. As used herein, a “nongaseous precursor” can be a precursor that is not sublimed or vaporized, and therefor is in solid or liquid form. A heater (e.g., a radiant heat lamp, resistive heater, and/or the like) coupled to and/or in thermal communication with the source vessel can heat up the source vessel to facilitate the vaporization and/or sublimation of the chemical precursor in the source vessel. The source vessel can comprise any suitable shape or size, such as a rectangular, square, and/or cylindrical shape. The source vessel can have an inlet and an outlet for the flow of a carrier gas through the source vessel. The carrier gas can be inert, for example, nitrogen, argon, or helium. Generally, the carrier gas conveys reactant vapor (i.e., precursor gas) (e.g., evaporated or sublimed chemical reactant) along with it through the vessel outlet and ultimately to a reaction chamber. In various examples, a source vessel comprises, consists essentially of, or consists of a sublimator and/or vaporizer. As such, wherever a “solid source vessel” is mentioned herein, a sublimator (such as a “solid source chemical sublimator”) and/or a vaporizer is also contemplated.

In various examples, each chemical reactant can be stored in a source vessel. For some solid substances (referred to herein as “solid source precursors,” “solid precursors,” “solid chemical reactants,” “solid reactants,” or the like), the vapor pressure at room temperature is so low that they are typically heated and/or maintained at very low pressures to produce a sufficient amount of reactant vapor for the reaction process. Vapor phase reactants (i.e., precursor gases) from solid or liquid substances can be useful for chemical reactions in a variety of industries.

In various examples, a source vessel can comprise a movable base. The movable base can define a lower boundary of an interior space of the source vessel. The movable base can move or translate up and down (or in any other suitable direction), thus, changing the volume of the interior space in which chemical precursor can be disposed. In various examples, the movable base can comprise a movable platform (e.g., that is curved, substantially flat, or any other suitable configuration) that moves up and down. The movable base can move between a lower position and a raised position, and/or to intermediate positions between the lower and raised positions. In various examples, the movable base can comprise a telescoping structure (e.g., comprising concentric parts that can slide/collapse into, or expand out of, themselves). For a telescoping structure, the lower position can be a contracted or collapsed position, and the raised position can be an expanded position.

In various examples, moving the movable base can be controlled or facilitated manually, mechanically, electromechanically, and/or can be partially or fully automated, for example using one or more sensors for automated feedback controlled by a controller and/or processor. In various examples, the reactor system can comprise one or more pressure sensors (i.e., pressure transducers, transmitters, and/or the like). Pressure sensors can be configured to measure a pressure within source vessel and/or gas lines through which precursor gas travels between components of the reactor system (e.g., between the source vessel and the reaction chamber), for example, in response to sublimation or vaporization of the chemical precursor in the source vessel. In various examples, a controller and/or processor can be in electronic communication (or operably coupled) with one or more of the pressure sensors, such that controller and/or processor can receive a pressure reading or data from the pressure sensors, and/or various other components of the system to execute various functions, operations, movements, and/or the like.

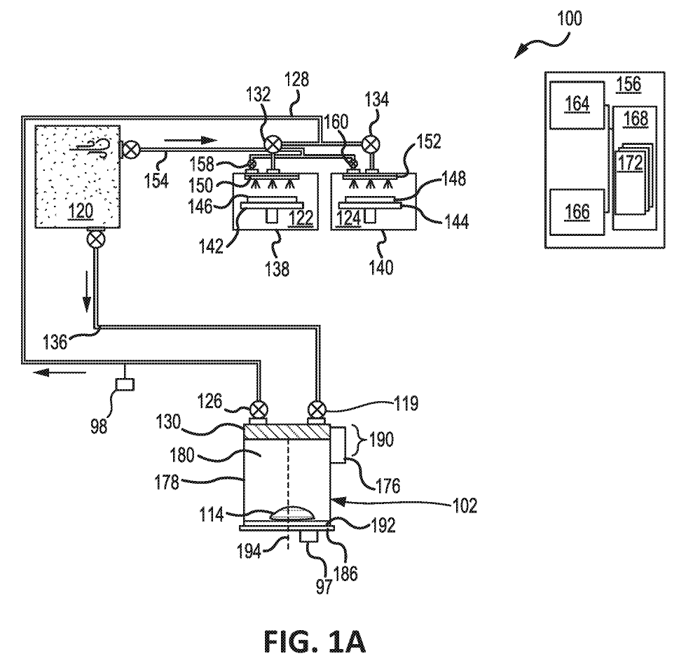

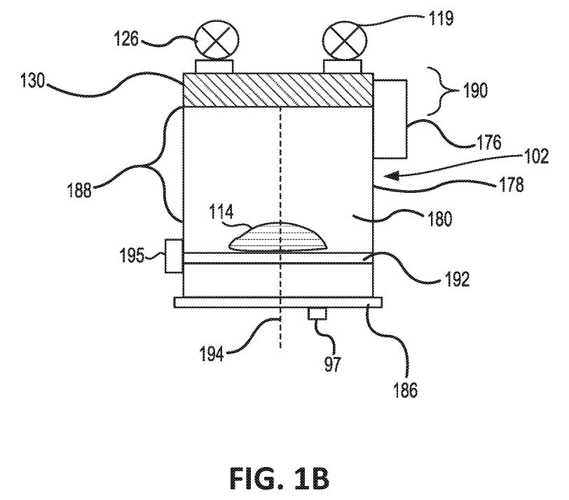

FIG. 1A is a schematic illustrating an example reactor system 100 including a source vessel 102 and/or one or more reactors 138 and 140 including respective reaction chambers 122 and 124. Reactors 138 and 140 can include respective susceptors 142 and 144 to hold respective substrates 146 and 148 during processing and gas distribution systems 150 and 152 to distribute one or more reactants/precursors to respective surfaces of substrates 146 and 148. Reactor system 100 can include a vacuum source for controlling vacuum pressure in one or more of reaction chambers 122 and 124. A reactant source can feed a gas-phase reactant, generated from a source vessel 102 comprising a nongaseous precursor, into gas-phase reactors. Reactors 138 and/or 140 can be gas-phase reactors. Source vessel 102 can contain solid precursor 114 (e.g., in a solid state). The solid chemical can comprise a chemical reactant including, for example, HfCl₄, ZrCl₄, AlCl₃, TaF₅, MoF₅, and/or SiI₄. Solid precursor 114 can be solid under standard conditions (e.g., room temperature and atmospheric pressure). It should be understood that the systems and methods referring to a solid precursor within a source vessel, and the sublimation thereof into a gas precursor, can also apply to a liquid precursor within a source vessel, and the vaporization thereof into a gas precursor.

A carrier gas source 120 can be coupled to source vessel 102 via carrier gas line 136 and can hold a carrier gas. Lid 130 of source vessel 102 can comprise a carrier gas valve 119 or have carrier gas valve attached thereto to regulate flow of the carrier gas from carrier gas source 120 into source vessel 102. Carrier gas source 120 can be fluidly coupled to reaction chambers 122 and 124 via gas line 154 and valves 158 and 160. In various examples, valves 158 and 160 can be controlled by one or more controllers. In response to being introduced into source vessel 102, the carrier gas can help transport vaporized and/or sublimed chemical reactants through vessel outlet valve 126 to reaction chamber 122 and/or 124. Chemical delivery line 128 can comprise valves 132 and 134 for controlling fluid communication of solid precursor 114 (in gas phase) and/or carrier gas from source vessel 102 to respective reaction chambers 122 and 124.

Source vessel 102 can be thermally coupled to one or more heating devices 176 (e.g., heaters, heating jackets, heating blocks, and/or radial heater) and/or one or more cooling devices 186. Such heating or cooling devices can serve to control or adjust the temperature of solid precursor 114 during refilling operations, material processing operations, and/or storage of solid precursor 114. Cooling devices 186 can comprise, a chill plate, cooling coils, variable pitch cooling coils, a cooling jacket, cooling fans, a Peltier cooler, and/or integrated coolant channels circulating coolant. As discussed in more detail herein, such heating devices 176 and cooling devices 186 can provide a temperature gradient within source vessel 102.

In various examples, heating device 176 can be coupled to and/or in thermal communication with source vessel 102 (e.g., at wall system 178 (e.g., a vessel body or housing) and/or lid 130). Wall system 178 and/or lid 130 can be configured to transfer heat and/or pressure from heating device 176 to solid precursor 114 (e.g., to evaporate or sublime solid precursor 114 for flowing through chemical delivery line 128). Movable base 192 can be cooled by a cooling device 186 (e.g., a cold plate) to a lower temperature than sidewalls of wall system 178 and/or lid 130 of source vessel 102. This can provide a temperature gradient along longitudinal axis 194 where the highest temperature in the system can be at the top portion 190 of source vessel 102 and the lowest temperature in the system can be at or proximate to movable base 192.

The temperature gradient extends between movable base 192 and top portion 190 including lid 130. In various examples, movable base 192 can be maintained at or below a first threshold temperature, while top portion 190 can be maintained at or above a second threshold temperature that is greater than the first threshold temperature. In various examples, the difference in temperature between movable base 192 and top portion 190 can be at least about 1° C, about 5° C, about 10° C, about 20° C, about 40° C, about 80° C, or about 160° C, or any value therebetween, or fall within any range having endpoints therein.

In various examples, during a material processing operation, heating device 176 can be configured to heat solid precursor 114 to a temperature sufficient to change the phase of solid precursor 114, such as to liquify and/or sublime solid precursor 114 (and/or vaporize a liquid precursor in source vessel 102). Once vaporized or sublimed into a gas precursor, the gas precursor can be transported via chemical delivery line 128 to reaction chambers 122 and/or 124 for substrate processing. Prior to vaporization and/or sublimation, solid precursor 114 may be stored as a solid in source vessel 102. Alternatively, solid precursor 114 may be stored in liquid phase (as a liquid precursor). Heating device 176 can be configured to heat source vessel 102 to a temperature sufficient to vaporize or sublimate the solid or liquid precursor in source vessel 102.

Reactor system 100 can comprise controller 156, which includes a processor 164, a user interface 166, and/or a memory 168. Processor 164 can be operably connected to user interface 166 (e.g., to receive user input and/or provide user output therethrough) and can be disposed in communication with memory 168. Memory 168 includes a tangible, non-transitory, machine-readable medium having a plurality of program modules/instructions 172 stored thereon that, in response to reading and/or execution by processor 164, cause processor 164 to execute certain operations. Among the operations are operations of a material layer deposition method, methods for refilling a source vessel 102, methods for determining precursor transfer, and/or methods for moving movable base 192 as discussed herein. As will be appreciated by those of skill in the art in view of the present disclosure, controller 156 may have a different arrangement or configuration in other examples and remain within the scope of the present disclosure.

With continued reference to FIG. 1A, reactor system 100 can comprise one or more pressure sensors 97, 98 (i.e., pressure transducers, transmitters, and/or the like). Pressure sensor 97 can be coupled to, and/or configured to measure a pressure within, source vessel 102. Pressure sensor 98 can be coupled to, and/or configured to measure a pressure within, chemical delivery line 128. Pressure sensor 97, for example, can detect pressure during vaporization and/or sublimation of the nongaseous precursor in source vessel 102, and/or in response to addition of nongaseous precursor to, or the flow of gas precursor out of, source vessel 102. In various examples, pressure sensors 97, 98 can sense pressure and/or detect a change in pressure automatically, partially automatically, or manually. In some examples, the processor can detect a change in the amount of solid precursor 114. In some examples, the processor can receive a pressure reading or data from pressure sensor 97. In response, the processor can determine or detects a change in the volume (e.g., overhead volume, as discussed herein) the interior space 180.

FIG. 1B is a schematic view of source vessel 102, in accordance with various examples. Source vessel 102 comprises a wall system 178 at least partially defining an interior space 180. Source vessel 102 can further comprise movable base 192, which can at least partially define interior space 180. Movable base 192 can be a lower boundary of interior space 180 available to comprise nongaseous precursor therein.

A nongaseous precursor can be disposed in interior space 180 (e.g., solid precursor 114). The portion of interior space 180 that is above the nongaseous precursor is an overhead volume 188. Overhead volume 188 can change as the amount nongaseous precursor changes. For example, overhead volume 188 can get larger as nongaseous precursor vaporizes and/or sublimes, or overhead volume 188 can get smaller as nongaseous precursor is added to source vessel 102.

In response to overhead volume 188 changing, movable base 192 can move to a different position. For example, pressure sensor 97 and/or 98 can detect pressure within source vessel 102 and/or chemical delivery line 128 and transmit pressure data to controller 156 (e.g., to processor 164). Controller 156 can receive the pressure data and determine a change in pressure within source vessel 102 and/or chemical delivery line 128 based on the received pressure data. Based on the pressure data and/or the determined pressure change, controller 156 can determine a change in overhead volume 188, and in response, controller 156 can command movable base 192 to move to compensate for the increase or decrease in overhead volume 188. Thus, an objective can be to keep overhead volume 188 as consistent as possible (e.g., substantially constant). Movable base 192 can be moved by any suitable means, such as via a motor 195 operably coupled to movable base 192 (e.g., moving mechanically and/or electromechanically), via gas injection below movable base 192 such that the pressure thereunder determines the position of movable base 192 between a lower position and raised position, and/or the like.

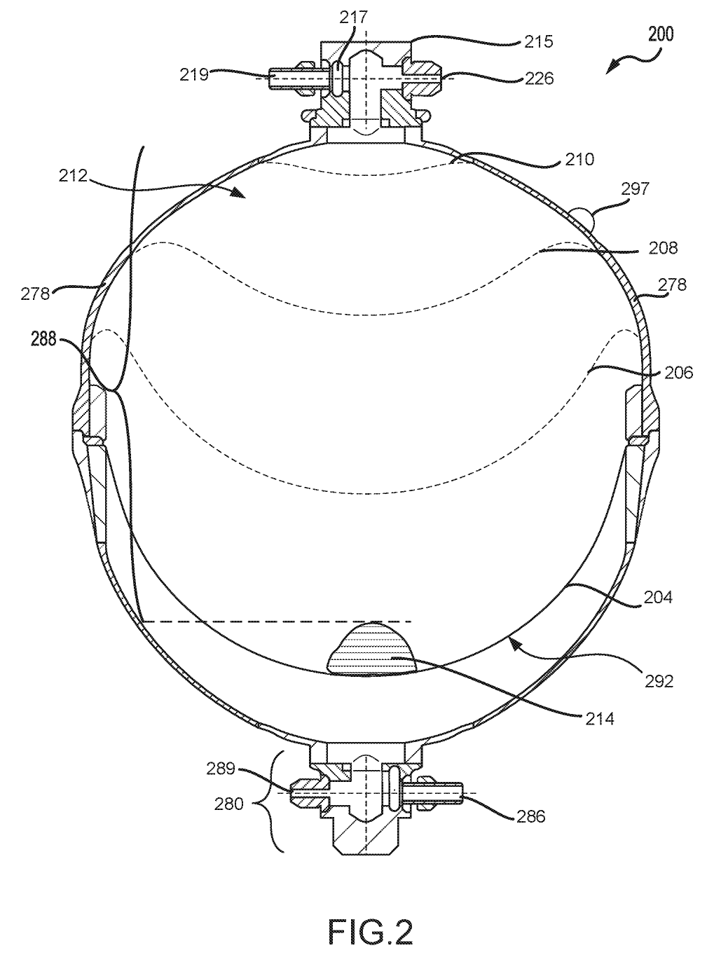

FIG. 2 illustrates a source vessel 200 (an example of source vessel 102), in accordance with various examples. Source vessel 200 can comprise a wall system 278 (an example of wall system 178) at least partially defining an interior space 212 (an example of interior space 180). Source vessel 200 can further comprise a movable base 292 (an example of movable base 192). Movable base 292 can at least partially define interior space 212. In various examples, the position of movable base can determine the amount of space provided by interior space 212 that can house or comprise a nongaseous precursor.

Source vessel can comprise a connecting portion 215 (e.g., as part of, or coupled to, wall system 278). Source vessel 200 can comprise a carrier gas inlet 219 (e.g., comprised in connecting portion 215). Carrier gas inlet 219 (an example of the carrier gas inlet controlled by carrier gas valve 119) can be fluidly coupled to a carrier gas source (e.g., carrier gas source 120), and can be configured to allow a carrier gas to flow therethrough and into source vessel 200. For example, carrier gas valve 217 can regulate the flow of carrier gas through carrier gas inlet 219 and into interior space 212. Source vessel 200 can comprise a vessel outlet 226 (e.g., comprised in connecting portion 215). Vessel outlet 226 (an example of the vessel outlet controlled by vessel outlet valve 126) can be fluidly connected between interior space 212 of source vessel 200 and a reaction chamber, such that gas precursor (and/or carrier gas) can flow from interior space 212, through vessel outlet 226, and to its next destination within the reactor system (e.g., a reaction chamber).

A nongaseous precursor (e.g., solid precursor 214) can be disposed in interior space 212 of source vessel 200. Solid precursor 214 can be disposed on movable base 292. The volume above the nongaseous precursor within interior space 212 can be an overhead volume 288 (an example of overhead volume 188). Thus, overhead volume 288 can change in response to the nongaseous precursor within source vessel 200 vaporizing and/or subliming, and/or in response to more nongaseous precursor being disposed into interior space 212.

Movable base 292 can move to change overhead volume 288. For example, movable base 292 can move in order to keep overhead volume 288 at a substantially constant volume (e.g., in response to overhead volume 288 increasing or decreasing from addition or removal of the nongaseous precursor). Accordingly, movable base 292 can move between positions, such as positions 204, 206, 208, and/or 210. Movable base 292 can comprise a telescoping structure. Accordingly, position 204 can be a fully collapsed or contracted position (i.e., a lower position), positions 206 and 208 can be intermediate positions, and/or position 210 may be a fully expanded position (i.e., a raised position).

In various examples, a pressure sensor 297 can be coupled (e.g., physically, electronically, operably, and/or the like) to source vessel 200, and can be configured to measure or detect a pressure within source vessel 200 (and/or interior space 212). The pressure within source vessel 200 can be monitored, for example by pressure sensor 297 and/or a controller (e.g., controller 156). Based on pressure data received from pressure sensor 297, the controller (and/or a processor therein) can determine overhead volume 288 as nongaseous precursor is added or removed from interior space 212, and can monitor overhead volume 288 and changes thereto. In various examples, the processor can detect a change in overhead volume 288 automatically. In various examples, based on the pressure from pressure sensor 297 and/or a detected change in overhead volume 288, the processor can determine and/or detect a change in the amount of solid precursor 214 in interior space 212.

The movable base 292 can be configured to move in response to the controller and/or processor detecting a change in pressure or nongaseous precursor amount within source vessel 200. For example, in response to the processor detecting overhead volume 288 increasing (e.g., from solid precursor 214 subliming and/or gas precursor flowing out of source vessel 200 via vessel outlet 226), the controller/processor can command movable base 292 to move to a position above its current position to decrease overhead volume 288 (e.g., moving from position 204 to position 206). Movable base 292 can move positions accordingly. As another example, in response to the processor detecting overhead volume 288 decreasing (e.g., from solid precursor 214 being added to source vessel 200), the controller and/or processor can command movable base 292 to move to a position below its current position to increase overhead volume 288 (e.g., moving from position 206 to position 204). Movable base 292 can move positions accordingly. In various examples, the controller and/or processor can determine changes in pressure and/or the amount of nongaseous precursor in source vessel 200 in real time or near real time (e.g., within less than 1, 3, 5, 10, or 30 seconds), and in response, movable base 292 can move substantially simultaneously. That is, the movable base can be configured to move substantially simultaneously with nongaseous precursor subliming or vaporizing, and/or with gas precursor (resulting from vaporization or sublimination of the nongaseous precursor) flowing out of source vessel 200. Thus, in various examples, the movable base can maintain a substantially constant overhead volume 288, which can minimize and/or prevent fluctuations in parameters within source vessel 200 (e.g., pressure and/or temperature) that can cause variations in processing (e.g., variations in precursor delivery rate and/or amounts to the reaction chamber).

As discussed herein, movable base 292 can be raised or lowered in any suitable manner, for example, via a motor (e.g., motor 195), and/or via hydraulics or pressure (via liquid or gas). In various examples, source vessel 200 can comprise an expansion gas system 280. Expansion gas system 280 can comprise an expansion gas inlet 289 and an expansion gas outlet 286. Expansion gas inlet 289 can be fluidly coupled to a gas source (e.g., a nonreactive or inert, and/or atmospheric, gas source). The gas source can supply gas to source vessel 200 to expand or raise movable base 292. To raise movable base 292, expansion gas can flow through expansion gas inlet 289, increasing pressure below movable base 292, thus raising movable base 292 to a higher position. To lower movable base 292, expansion gas disposed under movable base 292 can be released via expansion gas outlet 286, decreasing pressure below movable base 292, thus lowering movable base 292 to a lower position.

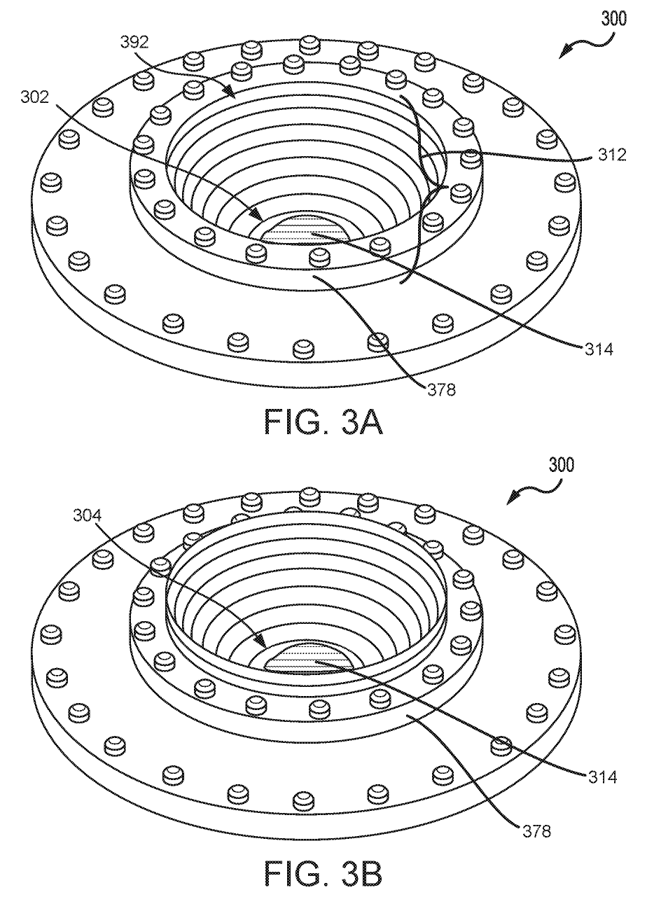

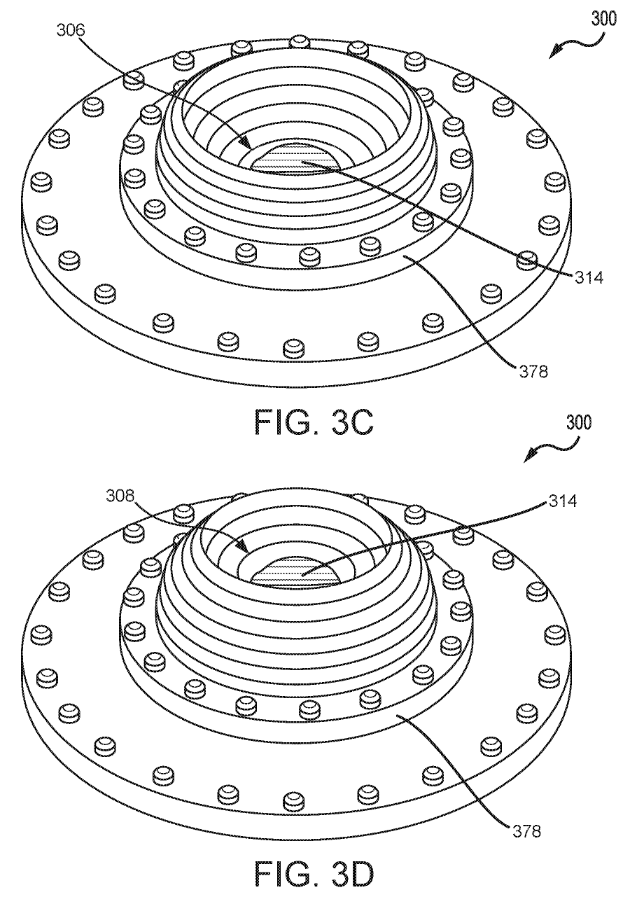

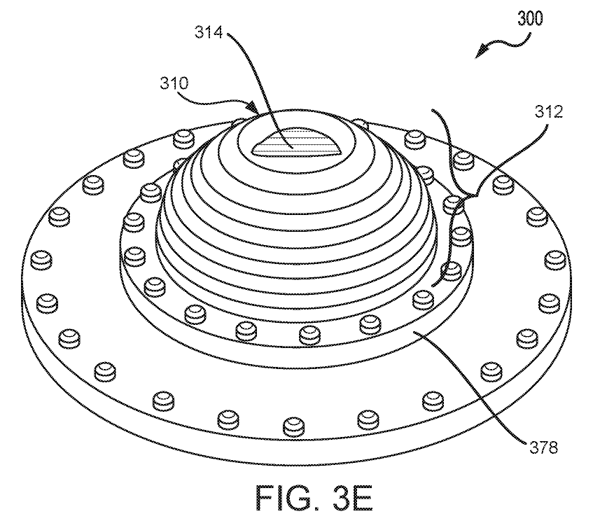

FIGS. 3A-3E representatively illustrate a source vessel 300 comprising a movable base 392 and a vessel foundation 378. A wall system can couple to foundation 378 to at least partially define an interior space of source vessel 300 (e.g., with movable base 392). Movable base 392 can comprise a telescoping structure 312. Telescoping structure can comprise a plurality of nesting segments that can collapse/contract into and/or alongside one another to lower movable base 392 and/or expand from one another to raise movable base 392. In various examples, movable base 392 can be configured to expand or collapse (i.e., raise or lower) between a plurality of different positions 302, 304, 306, 308, and/or 310.

Position 302 can be a fully contracted/collapsed position (a lower or lowest position), positions 304, 306, and/or 308 can be intermediate positions, and/or position 310 can be a fully expanded position (a raised position). That is, FIG. 3A representatively illustrates a fully contracted/collapsed position 302 (a lower or lowest position) of movable base 392 of a source vessel 300. FIG. 3B. representatively illustrates an intermediate position 304 of movable base 392 of a source vessel 300. Intermediate position 304 can be a higher position than collapsed position 302. FIG. 3C representatively illustrates an intermediate position 306 of movable base 392 of a source vessel 300. Intermediate position 306 can be a higher position than positions 304 and 302. FIG. 3D representatively illustrates an intermediate position 308 of movable base 392 of a source vessel 300. Intermediate position 308 be a higher position than positions 306, 304, and 302. FIG. 3E representatively illustrates an expanded position 310 (a raised or highest position) of movable base 392 of a source vessel 300. Expanded position 310 be a higher position than positions 308, 306, 304, and 302. The movable base 392 can contain and/or support solid precursor 314 thereon within source vessel 300 (movable base 392 can also be utilized to house and raise/lower a liquid precursor).

In various examples, during operation, (with an interior space of source vessel 300 being enclosed by a wall system) a first portion of solid precursor 314 can sublimed to produce a precursor gas (e.g., in response to heating the source vessel). In response to subliming solid precursor 314, the overhead volume (e.g., overhead volume 288 of source vessel 200) increases (because there is less solid precursor 314, and thus more space above solid precursor 314 in source vessel 300). In response to overhead volume 188 increasing, movable base 392 can move into a different position (e.g., a higher position). For example, movable base 392 can move from a lower position (e.g., position 302) to a higher position (e.g., one or more of positions 304, 306, 308, and/or 310) to decrease the overhead volume (e.g., to maintain the overhead volume at a substantially constant level).

In various examples, solid precursor 314 can be added into the source vessel 300, which can decrease the overhead volume in the interior space. In response, movable base 392 can be lowered to a lower position to increase the overhead volume (e.g., to maintain the overhead volume at a substantially constant level). “Substantially constant” can mean within 10% or 20% of previous and subsequent overhead volumes as nongaseous precursor is added to or removed from the source vessel.

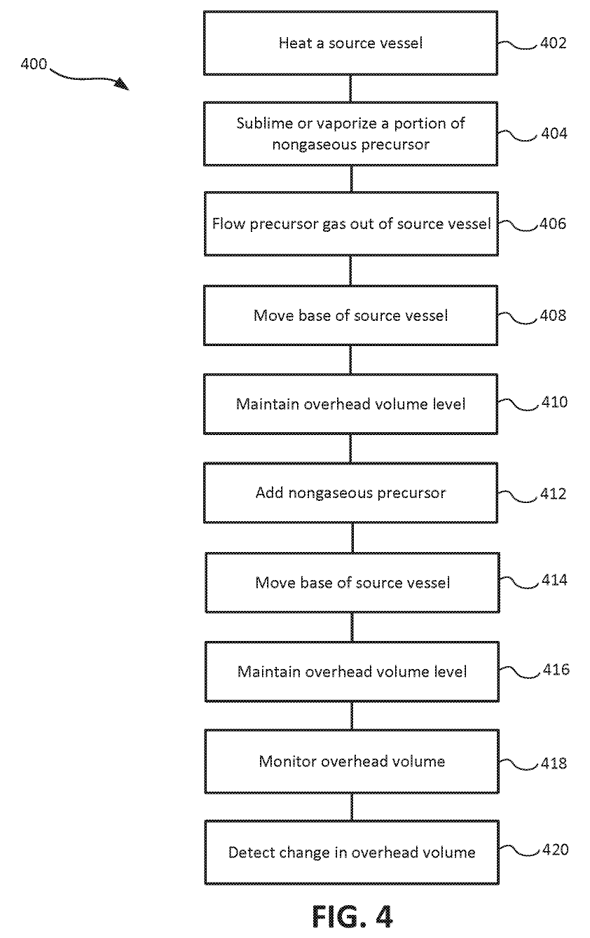

With reference to FIGS. 2 and 4, a method 400 of utilizing a source vessel 200 including a movable base 292 is illustrated. Source vessel 200 can comprise a nongaseous precursor disposed therein, resting on movable base 292. The nongaseous precursor can be a solid or liquid precursor (e.g., solid precursor 214). Source vessel 200 comprising the nongaseous precursor can be heated (step 402). In response, at least a portion of the nongaseous precursor can be sublimed or vaporized (step 404) (i.e., a portion of the nongaseous precursor can become gas precursor). Such heating can be completed by, for example, a heating device (e.g., heating device 174 in FIG. 1B) in thermal communication with the source vessel 200. In response to forming a precursor gas, the precursor gas can flow out of source vessel 200 (step 406) (e.g., through vessel outlet 226 toward a reaction chamber). The sublimation and/or vaporization of the nongaseous precursor can cause overhead volume 288 above the nongaseous precursor to increase. In response, the movable base 192 can be moved (step 408). For example, pressure sensor 297 (e.g., in conjunction with a processor) can measure the pressure in source vessel 200 (or interior space 212 thereof). The processor can receive the pressure readings from the pressure sensor(s) 297. Based on the pressure readings, the processor can determine an overhead volume 288, a change in overhead volume 288, and/or an amount decrease of nongaseous precursor. In response to determining that the overhead volume in source vessel 200 has increased, and/or that the amount of nongaseous precursor has decreased, the processor can command or otherwise cause movable base 292 to move to decrease the overhead volume. Thus, movable base 292 can move to a higher position. For example, with movable base 292 starting in lower position 204, movable base 292 can move to an intermediate position 206 or 208.

Movable base 292 can be moved in any suitable manner, such as via a motor and/or creating pressure under movable base 292 to expand the telescoping structure of movable base 292. In various examples, moving the movable base 192 may be controlled manually and/or moving the base can be partially or fully automated, for example using one or more sensors for automated feedback controlled by controller 156.

In response to moving the movable base 292, the overhead volume 288 can be maintained (step 410), e.g., at a substantially constant level. For example, in response to pressure sensor 297 transmitting pressure data and the processor detecting a change in pressure in source vessel 200, the movable base can move to maintain substantially the same overhead volume in source vessel 200.

In various examples, nongaseous precursor can be added into source vessel 200 (step 412). For example, as the nongaseous precursor is depleted in source vessel 200, source vessel 200 can be refilled with more nongaseous precursor. This can be completed via a refill process through a refill source vessel in fluid communication with source vessel 200. In response to the additional nongaseous precursor, overhead volume 288 in source vessel 200 can decrease. In response, movable base 292 can be moved (step 414), e.g., to increase overhead volume 288. Thus, the overhead volume can be maintained (step 416) at a desired and/or substantially constant level.

In various examples, moving movable base 292 in response to nongaseous precursor subliming and/or vaporizing (and exiting source vessel 200), and/or to nongaseous precursor being added to source vessel 200, can occur substantially simultaneously with such changes to the nongaseous precursor. For example, overhead volume 288 can be monitored (step 418). Overhead volume 288 can be monitored via any suitable method, such as via a processor receiving data from any suitable sensor, such as pressure sensor 297 detecting pressure in source vessel 200, a sensor detecting the weight of nongaseous precursor in source vessel 200, and/or the like. Sensor data can be transmitted to the processor, and the processor can calculate and/or detect a change in overhead volume (step 420) (e.g., based on the sensor data). In response to detecting a change in overhead volume 288, movable base 292 can be moved, as discussed herein.

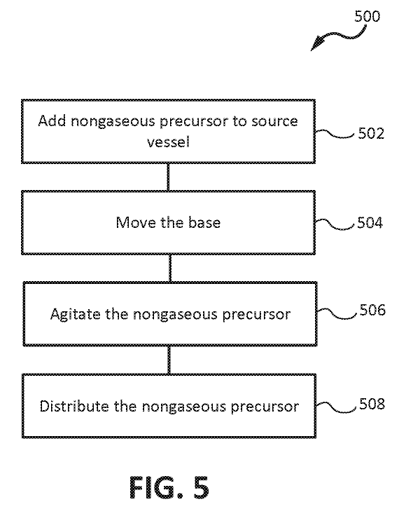

With additional reference to FIG. 5, method 500 for agitating a nongaseous precursor (e.g., solid precursor 214) can include adding nongaseous precursor to source vessel 200 (step 502). Movable base 292 can be moved (step 504) to agitate the nongaseous precursor (step 506). Movable base 292 can move before, during, and/or after the nongaseous precursor is added to source vessel 200. To agitate the nongaseous precursor, movable base 292 can be moved in any suitable manner, such as being pulsed (e.g., moved up and down, or side-to-side, in short distances in short periods of time, resembling vibration), vibrated, and/or the like. In response to such agitation, the nongaseous precursor can be distributed within source vessel 200 (step 508) (e.g., within interior space 212, over or across/along movable base 292), and/or the like. Such agitation can provide various benefits, such as mixing the nongaseous precursor (e.g., maintaining mixing of compounds and/or phases), preventing coagulation, and/or exposing greater surface area (e.g., of a powder to facilitate sublimation).

Any or all of the steps of methods 400 and/or 500 can be performed and/or facilitated by a controller and/or processor comprised in the respective reactor system, as appropriate.

Utilizing the systems and methods discussed herein can allow moving a movable base in a source vessel in response to nongaseous precursor being added or removed from (or turned to gas in) a source vessel, without requiring disassembly or decoupling of reactor components (e.g., to weigh a vessel or take other action) or substantially impacting the concentration, pressure, temperature, and/or any other parameters in the source vessel.

The structure and methods herein are discussed regarding a source vessel. It should be understood that the structures and methods discussed herein can be applied to any suitable vessel configured to hold a chemical (e.g., a nongaseous precursor), such as a remote refill vessel (e.g., configured to refill a source vessel fluidly coupled thereto) and/or the like.

The examples of the disclosure described above do not limit the scope of the claimed subject matter, since these are merely examples. The invention is defined by the appended claims and their legal equivalents. Any equivalent embodiments are intended to be within the scope of this disclosure. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A method, comprising:
heating a source vessel to a predetermined temperature, wherein the source vessel comprises a movable base and a wall system at least partially defining an interior space with a nongaseous precursor disposed therein, wherein the interior space comprises an overhead volume above the nongaseous precursor having a first volume;
subliming or vaporizing a first portion of the nongaseous precursor in the source vessel to produce a precursor gas in response to the heating the source vessel, causing the overhead volume in the interior space to increase to a second volume;
flowing the precursor gas out of the source vessel; and
moving the movable base in response to the subliming or vaporizing the first portion of the nongaseous precursor to decrease the overhead volume toward the first volume.

2. The method of claim 1, wherein the moving the movable base comprises applying pressure to the moveable base in response to the flowing the precursor gas out of the source vessel.

3. The method of claim 1, wherein the movable base comprises a telescoping structure, wherein the moving the movable base comprises expanding the telescoping structure into the second volume as the precursor gas flows out of the source vessel.

4. The method of claim 1, wherein the moving the movable base occurs substantially simultaneously to at least one of:
the subliming or vaporizing the first portion of the nongaseous precursor, or
the flowing the precursor gas out of the source vessel.

5. The method of claim 4, further comprising maintaining the overhead volume at a substantially constant volume.

6. The method of claim 1, further comprising adding more of the nongaseous precursor into the source vessel, thus decreasing the overhead volume in the interior space.

7. The method of claim 6, further comprising lowering the movable base to increase the overhead volume toward the first volume.

8. The method of claim 7, wherein the movable base comprises a telescoping structure, wherein the lowering of the movable base occurs substantially simultaneously to the adding more of the nongaseous precursor.

9. The method of claim 1, wherein the movable base is configured to move between a raised position and a lower position.

10. A method, comprising:
adding a nongaseous precursor into an interior space of a source vessel, wherein the source vessel comprises a movable base and a wall system at least partially defining the interior space, wherein the interior spaces comprises an overhead volume above the nongaseous precursor having a first volume,
wherein the overhead volume in the interior space decreases to a second volume in response to the adding the nongaseous precursor; and
moving the movable base to increase the overhead volume in response to the adding the nongaseous precursor into the interior space.

11. The method of claim 10, further comprising maintaining the overhead volume at a substantially constant level.

12. The method of claim 10, further comprising monitoring, by a processor, the overhead volume in the interior space.

13. The method of claim 12, further comprising:
detecting, by the processor, a change in the overhead volume in the interior space in response to the adding the nongaseous precursor to the interior space,
wherein the moving the movable base is in response to the detecting the change in the overhead volume.

14. The method of claim 10, further comprising removing a portion of the nongaseous precursor from the interior space of the source vessel, thus increasing the overhead volume in the interior space.

15. The method of claim 14, further comprising moving the movable base in response to the increasing the overhead volume.

16. A method, comprising:
adding a nongaseous precursor into an interior space of a source vessel, wherein the source vessel comprises a movable base and a wall system at least partially defining the interior space, wherein the interior spaces comprises an overhead volume above the nongaseous precursor having a first volume;
moving the movable base, wherein the nongaseous precursor is disposed on the movable base; and
agitating the nongaseous precursor.

17. The method of claim 16, further comprising distributing the nongaseous precursor at least partially across the movable base in response to the agitating the nongaseous precursor.

18. The method of claim 16, further comprising subliming or vaporizing a first portion of the nongaseous precursor in the source vessel to produce a precursor gas.

19. The method of claim 18, further comprising flowing the precursor gas out of the source vessel in response to the subliming or vaporizing of the first portion of the nongaseous precursor, causing the overhead volume in the interior space to increase.

20. The method of claim 19, further comprising moving the movable base in response to the flowing the precursor gas out of the source vessel to decrease the overhead volume.
